(19) United States
(12) Patent Application Publication
(10) Pub. No.: US 2024/0292635 A1
(43) Pub. Date: Aug. 29, 2024

(54) APPARATUSES BASED ON AND METHODS INVOLVING TRANSFER TECHNIQUE OF CARBON NANOTUBES FOR STRETCHABLE ELECTRONICS

(71) Applicant: The Board of Trustees of the Leland Stanford Junior University, Stanford, CA (US)

(72) Inventors: Zhenan Bao, Stanford, CA (US); Donglai Zhong, Palo Alto, CA (US); Yuanwen Jiang, Mountain View, CA (US); Can Wu, Stanford, CA (US)

(21) Appl. No.: 18/427,394

(22) Filed: Jan. 30, 2024

Related U.S. Application Data
(60) Provisional application No. 63/442,063, filed on Jan. 30, 2023.
(60) Provisional application No. 63/601,647, filed on Nov. 21, 2023.

(51) Int. Cl. H10K 10/84; H10K 10/46; H10K 85/20

(52) U.S. Cl. CPC H10K 10/84; H10K 10/466; H10K 10/484; H10K 85/221

(57) ABSTRACT

In certain examples, a semiconductor includes a transistor having a channel including semiconducting CNTs (carbon nanotubes) material, and having source and drain electrodes separated from each other by a distance that spans at least a portion of the channel and that is in a range from 100 nm to 50,000 nm. With current passing between the source and drain electrodes and through the channel, an interface material is used (sandwiched between a first surface region of the channel and the source electrode and between a second surface region of the channel and the drain electrode) to reduce contact resistance and, with the channel, facilitate a high charge-carrier mobility.

### BACKGROUND

In certain specific exemplary contexts, aspects of the present disclosure are directed to intrinsically-stretchable electronics that can intimately contact with tissue, hence making it an ideal platform for human-machine interfaces, wearables, and/or implantables. To realize the desired sensing, processing, and driving functions for advanced skin-like electronics, intrinsically-stretchable semiconductors with a high carrier mobility may be important. Semiconducting carbon nanotubes (S-CNTs) have shown high carrier mobility of 10-100 cm²/Vs in flexible transistors, but a reliable placement of S-CNTs on intrinsically-stretchable polymer dielectric or substrates is challenging. To achieve high-density S-CNTs by soaking deposition, a pre-treatment of dielectric using plasma has been used to improve the interaction between sorting polymers, PFPD, and polymer dielectric. However, this process can induce the large hysteresis of the transfer curves, which is caused by the injection of ions, even with only a light treatment. In addition, the long-time soaking in toluene can cause swelling and deformation of soft materials, which makes the alignment of different layers become extremely hard.

In certain other specific exemplary contexts, aspects of the present disclosure are also directed to intrinsically-stretchable electronics which can intimately contact with tissue (e.g., applicable for human-machine interfaces, wearables, and implantables) and with such intrinsically-stretchable electronics realizing desired levels of sensing, processing, and driving functions for advanced skin-like electronics. In these contexts, both high performance intrinsically-stretchable transistors and large-scale integrated circuits are desirable/needed. Towards this aim, substantial efforts have been made to develop stretchable electronics through both material innovation and device engineering. Challenges remain in realizing both high spatial resolution and excellent electrical properties. Although recent attempts in material design resulted in directly photo-patternable conductors, semiconductors, and dielectric layers, together with improved device density, the electrical performance of the stretchable devices is still orders of magnitude lower than most flexible ones made of thin films, particularly at short channel lengths due to low semiconductor carrier mobility and high metal-semiconductor contact resistance. At the circuit level, the largest integration achieved to date with intrinsically-stretchable materials was comprised of only 30 transistors, and the highest operation speed reported was only 330 Hz because of the low device yield, low-conductivity interconnect and high parasitic effects.

These and other matters have presented challenges to such implementations, for a variety of applications.

### SUMMARY OF VARIOUS ASPECTS AND EXAMPLES

Various examples/embodiments presented by the present disclosure are directed to issues such as those addressed above and/or others which may become apparent from the following disclosure. For example, some of these disclosed aspects are directed to methods and devices that use or leverage from materials and/or processes to manufacture stretchable semiconductors, such as field-effect transistors, which can be implemented with closely-spaced source and drain electrodes and with high-mobility of charge carriers during operation of the semiconductor. Other exemplary aspects and/or example embodiments of the present disclosure are discussed below.

Certain other aspects and/or applications may include or be directed to: providing device stability through encapsulation and interface engineering; building N-type intrinsically-stretchable transistors to enable CMOS logic to reduce power consumption; enhancing device performance and uniformity by a self-aligned source/drain fabrication process; making an active-matrix transistor array for a stretchable display or an on-skin sensing application; and making an on-skin NFC tag for performing health monitoring.

In an exemplary apparatus, the apparatus includes a stretchable semiconductor having a channel, source and drain electrodes, and an interface material. The channel includes a surface portion that has semiconducting CNTs (carbon nanotubes). The source and drain electrodes includes a first electrode and a second electrode. The first and second electrodes are separated from each other by a distance that spans at least a portion of the channel and that is in a range from 100 nm to 50,000 nm. The interface material is sandwiched between a first surface region of the channel and the first electrode, and between a second surface region of the channel and the second electrode. The interface material reduces contact resistance and, with the channel, facilitates mobility of charge carriers during operation of the semiconductor.

In one more-particular example, the channel and the source and drain electrodes are part of a transistor, and the surface portion of the channel includes a non-etched material surface having semiconducting CNTs.

In connection with other more specific examples, there are numerous further exemplary aspects of the present disclosure which may build on one or more of the above characterizations. For example, the semiconductor can be at least partially intrinsically-stretchable due to material of the semiconducting CNTs forming a network, and the apparatus can additionally include at least one other intrinsically-stretchable layer arranged adjacent to a portion of material including the channel. The distance can be in the range from 100 nm to 10 micron, and at least one of the source and drain electrodes can include one or more of: metallic CNTs and material having metal and polymer. In some examples, the CNTs are characterized at least in part by a field-effect mobility in a range from 1 cm²/Vs to 100 cm²/Vs, and the channel has a profile characterized by a dense semiconducting CNT path along a majority of a length between the first electrode and the second electrode. Additionally, the channel can have a short channel length that is characterized by a transconductance normalized by channel width of at least 0.8 nS μm⁻¹. The channel can be composed of a material that is susceptible to damage from a plasma etching process. The surface portion of the channel can includes a non-etched surface along part of the length between the first electrode and the second electrode.

In another example, the semiconductor, at an interim stage of manufacture of the semiconductor, can include a patterning structure. The patterning structure can include at least a portion of one of the source and drain electrodes and be composed of a material having metal-CNTs.

In other examples of the present disclosure, the semiconductor includes a stretchable layer portion in which the channel resides and, in such examples, the semiconductor can include multiple layers, and each of the multiple layers can be composed of a stretchable polymer-based material. In one more particular example, the channel can have a length of less than 10 μm and a thickness not greater than 20 nm for a semiconducting CNT network. In yet further particular examples, a channel thickness of less than 5 nm is implemented to reduce off-current and full-gating of the channel, and alternatively a channel thickness less than 2 nm is even more desirable for these same advantages. In the above and other related examples, a transistor (represented by the channel and S/D regions) can operate with a contact resistance of less than 1 MΩ μm and high-carrier mobility (e.g., characterized as being greater than 10 cm²/Vs). The semiconductor can further include at least one dielectric material that is non-ionic and that is sandwiched by the channel and a gate electrode.

In yet other related examples according to the present disclosure, the apparatus can include contacts respectively connected to the source and drain electrodes and along a first plane. The surface portion of the channel is along a second plane that intersects with at least one of the source and drain electrodes. The surface portion can include a surface, on a side of the channel facing the first plane and that is without etch-based damage or etch-based residual material.

The distance that separates the first and second electrodes can be in a range from 100 nm to 400 nm in some examples.

The channel can have a shape that is circular, elliptical and/or that corresponds to a shape with a plurality of far-perimeter boundaries that are curved or rounded, in certain exemplary apparatuses according to the present disclosure. In such examples, it has been unexpectedly discovered that the channel shape facilitates cancellation of on-current variations.

In certain examples (which may or not include other features disclosed herein), the interface material can include one or a combination of two or more of palladium (Pd), gold (Au), platinum (Pt), titanium (Ti), and an organic dopant. In other examples, portions of the first electrode and the second electrode can be arranged along a plane that is parallel to a different plane along which a surface of the channel is arranged. The different plane can a plane that is displaced relative to the plane along which the portions of the first electrode and the second electrode are arranged.

Other examples have the channel extending along a plane and being characterized by a configuration that maintains physical resilience under strain in response to being stretched in at least one of a direction parallel to that plane and a direction perpendicular to a direction in which charge is transported. The orientation and configuration of the channel facilitate cancellation of on-current variations across different segments of the channel.

According to some examples, the apparatus can include patterned metallic contact electrodes that are connected to the source and drain electrodes and include at least one of M-CNTs a thin metal layer or an organic dopant.

Another exemplary apparatus includes a semiconductor that has a channel, source and drain electrodes, an interface material, and metallic contact electrodes. The channel can include material having sorted semiconducting carbon nanotubes (S-CNTs), and have a shape that facilitates cancellation of on-current variations. The channel can include a portion having a plurality of rounded corners. The source and drain electrodes include a first electrode and a second electrode that are separated from each other by a distance. The distance spans at least a portion of the channel and is in a range from 100 nm to 5000 nm. The interface material is sandwiched between a first surface region of the channel and the first electrode and between a second surface region of the channel and the second electrode. The interface material reduces contact resistance and, with the channel, facilitates mobility of charged carriers during operation of a transistor that includes the channel. The metallic contact electrodes are secured to the source and drain electrodes and include at least one of S-CNTs and a thin metal layer or an organic dopant. The channel is part of a thin-film transistor that operates in a steady state at one or more switching frequencies of at least 10 KHz.

Another specific example involves a semiconductor-based apparatus having a stretchable semiconductor (e.g., one or more transistors) having: a channel including a surface portion having semiconducting CNTs (carbon nanotubes); a first electrode and a second electrode separated from each other by a distance that spans at least a portion of the channel and that is in a range from 100 nm to 50,000 nm; and an interface region to reduce contact resistance and facilitate mobility of charge carriers during operation of the semiconductor, the interface region including respective interface portions between the channel and the first electrode and between the channel and the second electrode and including a surface region of the channel that is without etch-based damage or etch-based residual material and that is between the first and second electrodes and on the contacts side of the channel. In various more specific examples, the region may include (optionally) an interface material, sandwiched between one or more portions of the channel and one or more of the electrodes, to reduce the contact resistance.

In yet another specific example, a method involves a semiconductor having a channel that includes semiconducting CNTs (carbon nanotubes) material and source and drain electrodes separated from each other by a distance in a range from 100 nm to 50,000 nm. The method includes causing current to pass between the source and drain electrodes and through the channel, while using an interface material that is sandwiched between a first surface region of the channel and the source electrode and between a second surface region of the channel and the drain electrode, to reduce contact resistance. The method additionally includes facilitating a high charge-carrier mobility with the channel.

In certain other examples which may also build on the above-discussed aspects, methods and semiconductor structures are directed to providing for an interim stage of manufacture of the semiconductor a patterned structure that includes at least a portion of one of the source and drain electrodes, which are composed of a material having metal-CNTs. The method can include providing a surface of the channel that faces a plane along which the source and drain electrodes are to interface with at least one of a plurality of contacts. The surface of the channel is undamaged by an etchant and is free of etch-based residual material.

The disclosed methods can include, in instances in which the semiconductor is intrinsically-stretchable, subjecting the semiconductor stretch under a level of strain, in a range from 60% strain to 100% strain. Concurrently with the stretch, the method includes operating the semiconductor in steady state at one or more switching frequencies of at least 10 kHz and causing current to pass between the source and drain electrodes and through the channel with a charge-carrier mobility of at least 10 cm²/Vs.

Consistent with the disclosed methods, facilitating the charge-carrier mobility with the channel has the charge-carrier mobility in a range from 10 cm²/Vs to 100 cm²/Vs.

In some methods, the channel has a non-etched, smooth surface region between the source and drain electrodes.

In more specific examples related to the above methodology and/or devices, a method for manufacturing such a device may include (1) spin-coating dextran onto a (e.g., silicon) substrate, baking the coated substrate, and then immersing the baked substrate into a semi-purified S-CNT solution; (2) washing the substrate having the deposited S-CNTs (e.g., by toluene for 10 min (e.g., twice), drying the washed structure (e.g., using N₂), and then baking the dried structure; (3) spin-coating poly(methyl methacrylate) (“PMMA”, e.g., 495K A4) or other polymer, (e. g. SEBS, SBS, PMMA-PnBA-PMMA elastomer), onto the baked structure having the as-deposited S-CNTs and then drying; and (4) fixing edges of the structure after spin-coating the polymer, and then releasing the polymer (e.g., in de-ionized water) before putting the structure having the S-CNTs onto a fabricated dielectric.

The above discussion is not intended to describe each aspect, embodiment or every implementation of the present disclosure. The figures and detailed description that follow also exemplify various embodiments.

### BRIEF DESCRIPTION OF FIGURES

Various example embodiments, including experimental examples, may be more completely understood in consideration of the following detailed description in connection with the accompanying drawings, each in accordance with the present disclosure, in which:

FIG. 1A is a three-dimensional view of an exemplary intrinsically stretchable semiconductor, CNT transistor, according to certain exemplary aspects of the present disclosure;

FIG. 1B is a top, microscopic view of a transistor consistent with the transistor of FIG. 1A, according to certain exemplary aspects of the present disclosure;

FIG. 1C illustrates chemical structures in the transistor of FIGS. 1A and 1B, according to certain exemplary aspects of the present disclosure;

FIG. 1D-1, FIG. 1D-2, FIG. 1D-3, FIG. 1D-4, FIG. 1D-5, and FIG. 1D-6 illustrate structures produced by a process flow for fabricating a high-performance intrinsically stretchable semiconductor, according to certain exemplary aspects of the present disclosure;

FIG. 2A-1, FIG. 2A-2, and FIG. 2A-3 illustrate structures produced by a process flow for patterning M-CNT electrodes, according to certain exemplary aspects of the present disclosure;

FIG. 2B-1, FIG. 2B-2, FIG. 2B-3, FIG. 2B-4, FIG. 2B-5, and FIG. 2B-6 illustrate a process of making PMMA/metal stack structures, according to certain exemplary aspects of the present disclosure;

FIG. 3A-1, FIG. 3A-2, FIG. 3A-3, FIG. 3A-4, FIG. 3A-5, and FIG. 3A-6 show structures made in a process of preparing a bottom gate (BG) of an intrinsically stretchable transistor, according to certain exemplary aspects of the present disclosure;

FIG. 4A-1, FIG. 4A2, FIG. 4B, FIG. 4C-1, FIG. 4C-2, and FIG. 4C-3 illustrate patterning of a gate dielectric consistent with the stretchable semiconductor disclosed herein, according to certain exemplary aspects of the present disclosure;

FIG. 5A-1, FIG. 5A-2, FIG. 5A-3, and FIG. 5A-4 represent a schematic diagram showing the process of patterning low-K SEBS dielectric layer based on photolithography and oxygen plasma etching, according to certain exemplary aspects of the present disclosure;

FIG. 6A-1, FIG. 6A-2, FIG. 6A-3, FIG. 6A-4, FIG. 6A-5, and FIG. 6A-6 illustrate structures made in the process of transferring of S-CNTs as a device channel, according to certain exemplary aspects of the present disclosure;

FIG. 6B shows an exemplary semiconductor having Au contact electrodes and a channel, according to certain exemplary aspects of the present disclosure;

FIG. 6C is a graph showing field-effect mobility as a function of gate voltage for a transistor, according to certain exemplary aspects of the present disclosure;

FIG. 7-1, FIG. 7-2, FIG. 7-3, FIG. 7-4, FIG. 7-5, and FIG. 7-6 illustrate structures made in the process of patterning S-CNTs, according to certain exemplary aspects of the present disclosure;

FIG. 8A shows a semiconductor structure that does not include a Pd material, according to certain exemplary aspects of the present disclosure;

FIG. 8B shows a semiconductor structure that includes a Pd material, according to certain exemplary aspects of the present disclosure;

FIG. 8C is a graph that shows the scaling behavior of transistors consistent with the semiconductor structures of FIGS. 8A and 8B, according to certain exemplary aspects of the present disclosure;

FIG. 8D is a graph that shows a comparison of contact resistances under different overdrive voltages for transistors consistent with the semiconductor structures of FIGS. 8A and 8B, according to certain exemplary aspects of the present disclosure;

FIG. 9A-1, FIG. 9A-2, FIG. 9A-3 FIG. 9A-4, FIG. 9A-5, and FIG. 9A-6 illustrate patterning of interconnects, according to certain exemplary aspects of the present disclosure;

FIG. 10 shows a transistor having a bottom-gate, bottom-contact CNT-TFT, according to certain exemplary aspects of the present disclosure;

FIG. 11 illustrates a circular CNT-TFT, according to certain exemplary aspects of the present disclosure; and

FIG. 12 illustrates a circular CNT-TFT under strain, according to certain exemplary aspects of the present disclosure.

While various embodiments discussed herein are amenable to modifications and alternative forms, aspects thereof have been shown by way of example in the drawings and will be described in detail. It should be understood, however, that the intention is not to limit the disclosure to the particular embodiments described. In addition, the term “example” as used throughout this application is only by way of illustration, and not limitation.

### DETAILED DESCRIPTION

Aspects of the present disclosure are believed to be applicable to a variety of different types of apparatuses, systems and methods involving devices characterized at least in part by a semiconductor (e.g., a transistor) having closely-arranged source and drain electrodes and a channel that includes CNTs (e.g., with an interface material between portions of the channel and the source/drain electrodes to reduce contact resistance and facility high-carrier mobility). In exemplary devices of this type, high-carrier mobility is in the range from 10 cm²/Vs to 100 cm²/Vs, and the source and drain electrodes are separated from one another by less than 50,000 nm, and the channel is formed without etching-based damage at a surface between the source and drain electrodes. While the present disclosure is not necessarily limited to such aspects, an understanding of specific examples in the following description may be understood from discussion in such specific contexts.

Accordingly, in the following description various specific details are set forth to describe specific examples presented herein. It should be apparent to one skilled in the art, however, that one or more other examples and/or variations of these examples may be practiced without all the specific details given below. In other instances, well-known features have not been described in detail so as not to obscure the description of the examples herein. For case of illustration, the same connotation and/or reference numerals may be used in different diagrams to refer to the same elements or additional instances of the same element. Also, although aspects and features may in some cases be described in individual figures, it will be appreciated that features from one figure or embodiment (and/or as set forth in one or more of the appended claims) can be combined with features of another figure or embodiment even though the combination is not explicitly shown or explicitly described as a combination.

Exemplary aspects of the present disclosure are related to reducing contact resistance and facilitating high carrier mobility between source-drain electrodes and a CNT channel in a semiconductor. In an exemplary structure an interface material is disposed between respective surface regions of the channel and the source/drain electrodes.

In other particular examples, the present disclosure is directed to a method and/or an apparatus involving high-density S-CNTs on a polymer-based dielectric material, with the apparatus and/or method including or resulting from a combination of two or more of the following representative steps: (1) spin-coating dextran (e.g., 50 mg/ml) onto (e.g., Si/SiO₂) a silicon substrate, baking the coated substrate (e.g., at 150 degrees C. for 30 mins), and then immersing the baked substrate into a semi-purified S-CNT solution; (2) washing the substrate having the deposited S-CNTs (e.g., by toluene for 10 min twice, drying the washed structure using N₂, and then baking the dried structure (e.g., 150 degrees C. for 30 min); (3) spin-coating poly(methyl methacrylate) (“PMMA”) 495K A4 (e.g., 40 mg/ml in anisole) or other polymer, (e. g. SEBS, SBS, PMMA-PnBA-PMMA elastomer) onto the baked structure having the as-deposited S-CNTs (e.g., at 600 rpm for 90 s, and then at 4000 rpm for 20 s, and dried overnight at room temperature); and (4) fixing edges of the structure after spin-coating polymer by polyimide tapes, and then releasing the polymer in de-ionized (“DI”) water before putting the structure having the S-CNTs onto a fabricated dielectric.

In yet other particular examples, the present disclosure is directed to a method and/or an apparatus which addresses the above and other challenges by a combination of innovations in materials, fabrication process, device engineering, and circuit design, which enables intrinsically-stretchable electronics with high electrical driving capability and high operation speed, and large-scale circuit integration with high transistor density. For example, one such method according to the present disclosure is directed to a (e.g., metal-assisted) lift-off method to pattern metallic CNTs and/or metal particles (e.g., M-CNTs/Pd) as contact electrodes to achieve low contact resistance (e.g., <1 MΩ μm) with semiconductors and small channel length (e.g., less than 1 μm). The method contact electrodes can be secured to source and drain electrodes of a thin-film transistor, which can operate in a steady state at one or more switching frequencies of at least 10 kHz. Other exemplary ranges of switching frequencies include 10 kHz-30 kHz, 20 kHz-50 kHz, 50 kHz-100 kHz, and 10 kHz-100 kHz.

In one particular experimental example, thiol-ene reaction is used to pattern high-kappa (high-k); elastic dielectric (nitrilebutadiene rubber, NBR) as a gate dielectric to reduce supply voltage; a method is developed to form high-mobility semiconducting CNTs (e.g., >20 cm² V⁻¹ s⁻¹) as a channel; a method is developed to pattern smooth poly(3,4-ethylenedioxythiophene) polystyrene sulfonate (“PEDOT:PSS”) with small feature size (e.g., <1 μm) as a gate electrode to achieve low gate leakage; and high conductivity interconnects (e.g., eutectic gallium-indium alloy, E-GaIn) are combined with a high-density (e.g., linewidth ˜2 μm) and high-performance transistor array(s) to realize large-scale integration and high-speed operation, including but not limited to very-large scale patterned transistors in one or more arrays (e.g., high-density transistor configurations). In certain experimental and/or proof-of-concept examples, the as-fabricated transistors have a device yield, in various examples, of greater than 90%, 95% and 99% for certain um channel lengths (Lch), and, under 100% strain, with charge-carrier mobility of at least 20 cm²/Vs (and in some examples at least 21 cm²/Vs or as high 21.5 cm²/Vs), and a record transistor density of 100,000 cm⁻² including interconnects. The drive current reached ˜2.0 μA μm⁻¹ under a supply voltage of 5 V, which is comparable to state-of-the-art flexible transistors, including those based on CNT, oxide, organics and polycrystalline silicon (poly-Si) structures for the first time. Based on the high-density transistor array, a 527-stage ring oscillator (RO) is fabricated consisting of 1056 transistors and 528 logic gates, which effectively realized the first large-scale integration (LSI) of intrinsically stretchable electronics. In addition, with the reduced parasitic capacitance and resistance, a recorded-high operation speed with a stage switching speed of >1 MHz is further achieved. Also related to these approaches/aspects, for specific embodiments, certain advantages were realized such as those including the following: (1) a high device density of 100,000 transistors/cm² including interconnecting lines (even greater than previously reported structures without interconnects having 42,000 transistors/cm²); (2) A high carrier mobility of at least 20 (e.g., ˜21.5) cm²/Vs under 100% strain and a high transconductance (at least 0.5 μS μm⁻¹) with ˜1,000 times enhancement over all other stretchable transistors; (3) The first intrinsically-stretchable large-scale integrated circuit with 1,000 transistors and 500 logic gates; and (4) A high stage switching frequency of 1 MHz. With the reduced parasitic capacitance and resistance, as well as optimized circuit design, realization of a 3-stage ring oscillator with a stage switch frequency of 1.14 MHZ (e.g., ˜1,000 times higher than certain previous reports) is achieved.

Compared with flexible electronics and extrinsically-stretchable electronics, this technology as disclosed herein has further advantages in the following aspects: a high deformability and mechanical robustness attributable to the low-modulus of the substrate and low-modulus mismatch between the substrate and devices; and the ability to maintain intimate tissue contact while accommodating movement and size changes, hence making the disclosed structure ideal for human-machine interfaces, wearables, and implantables.

Consistent with the above aspects, such a manufactured device or method of such manufacture may involve aspects presented and claimed in U.S. Provisional Application Ser. No. 63/442,063 filed on Jan. 30, 2023 (STFD.449P1/S22-399) with Appendices (A, B, C-i, C-ii and D), and presented and claimed in U.S. Provisional Application Ser. No. 63/601,647 filed on Nov. 21, 2023 (STFD.449P2 S22-399) with Appendices (A, B, C-1, C-2), and for each of these U.S. Provisional Applications, priority is claimed. To the extent permitted, such subject matter is incorporated by reference in its entirety generally and to the extent that further aspects and examples (such as experimental and/more-detailed embodiments) may be useful to supplement and/or clarify.

Consistent with the present disclosure, human-machine interfaces in applications such as wearable and implantable electronic devices can include semiconductor structures consistent with the disclosed semiconductor structures made according to the disclosed methods. Such devices, particularly those having semiconductor structures that are operable with high carrier mobility and at high switching frequencies, may be realized using a patterning and lift-off process. By using a lift-off process (as opposed to an etching step), source/drain (“S/D”) electrodes, such as metal based S/D electrodes, can be formed and manufactured with a small distance or gap separating the S/D electrodes. A surface of a thin, S-CNT-based channel, which is undamaged by etching, is disposed to couple the S/D electrodes. In connection with the present disclosure, it has been discovered that (e.g., metal-based) etching processes create undesirable conductive remnants or segments (such as shorts) along the surface of the channel and/or damage very thin channels. This may be especially apparent, in connection with such experimental examples, wherein such thin channels have thicknesses of less than or equal to about 10 nm. Such undesirable surface-related features create problems in terms of optimizing carrier mobility and switching speed capability, yield and/or consistency in the manufacturing of the devices. By using such a lift-off process, instead of an etching process to expose the surface of the channel between the S/D electrodes, these problems can be avoided and these features of the semiconductor (e.g., one or more transistors) are significantly enhanced.

As noted above, certain exemplary aspects of the present disclosure involve methodology and structures directed to improving the high carrier mobility between an S-CNT channel and source/drain electrodes and these attributes are facilitated by avoiding the use of an etchant (associated with the above-noted problems, so that the channel surface is not damaged) and instead, by using a lift-off process (as exemplified herein) for exposing the S/D electrodes and channel.

Various experimental examples, some of which are discussed herein, have demonstrated that various characterized aspects, structures and methodologies (such as but not limited those indicated above) may be used in one or more semiconductive devices (aka semiconductors) to form semiconductor circuits and devices including but not limited to one or a combination of the various high-level attributes and/or applications. These experimental (e.g., proof-of-concept examples), are discussed in more detail below and in connection with the drawings.

To achieve high-performance, stretchable CNT transistors with various features (such as high mobility and high stretchability, material selection, fabrication processes, and/or device structures) have been combined to enable intrinsically stretchable electronics with high electrical driving capability and high operation speed. In addition, the structures support large-scale circuit integration with high transistor density. The structures feature a high-mobility channel material (e.g., high-purity S-CNTs), low-contact-resistance source/drain (S/D) electrodes (e.g., M-CNTs/palladium (Pd)), high-ϵ elastic dielectric (e.g., NBR), a smooth gate electrode (e.g., PEDOT:PSS), and high conductivity stretchable interconnects (e.g., eutectic gallium-indium alloy, (EGaIn)).

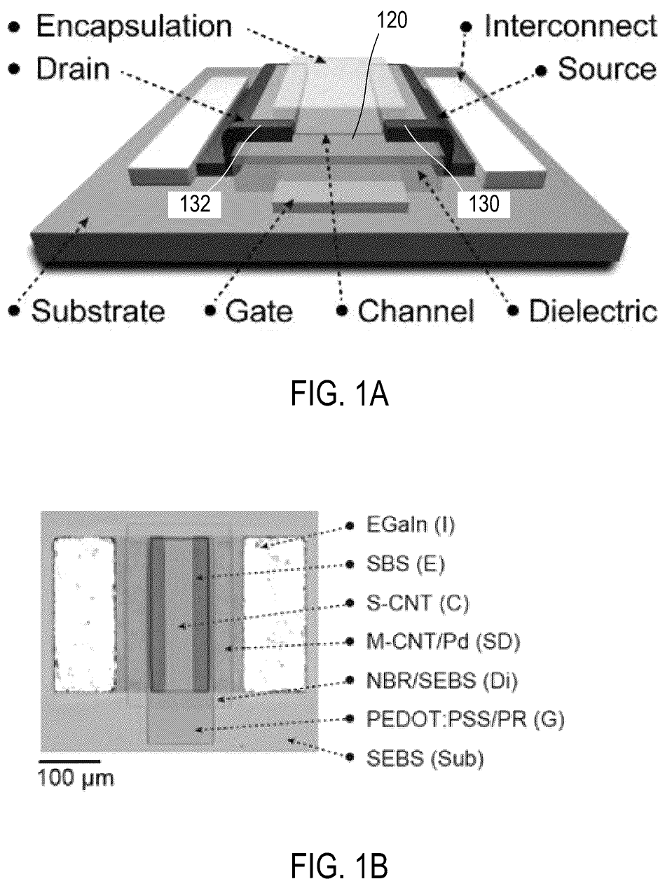

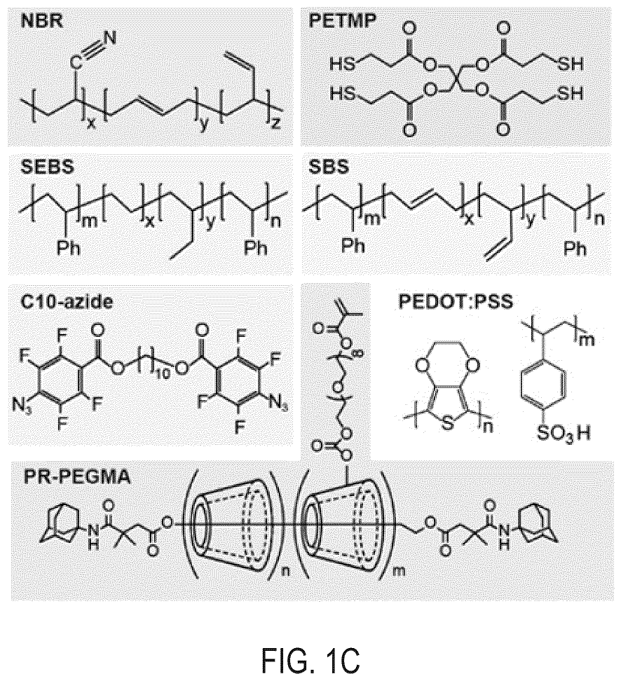

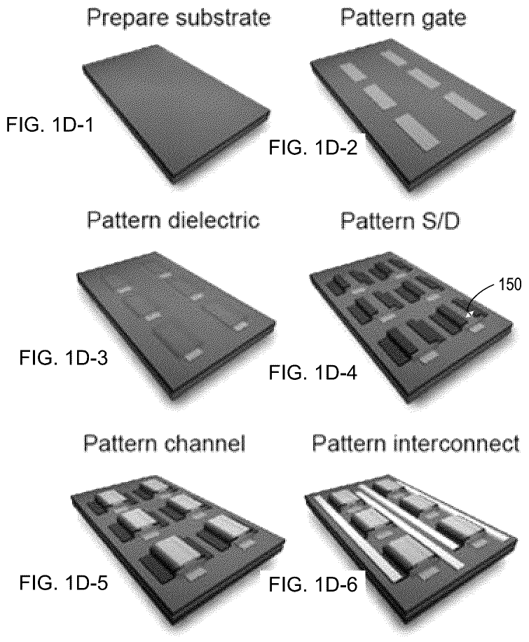

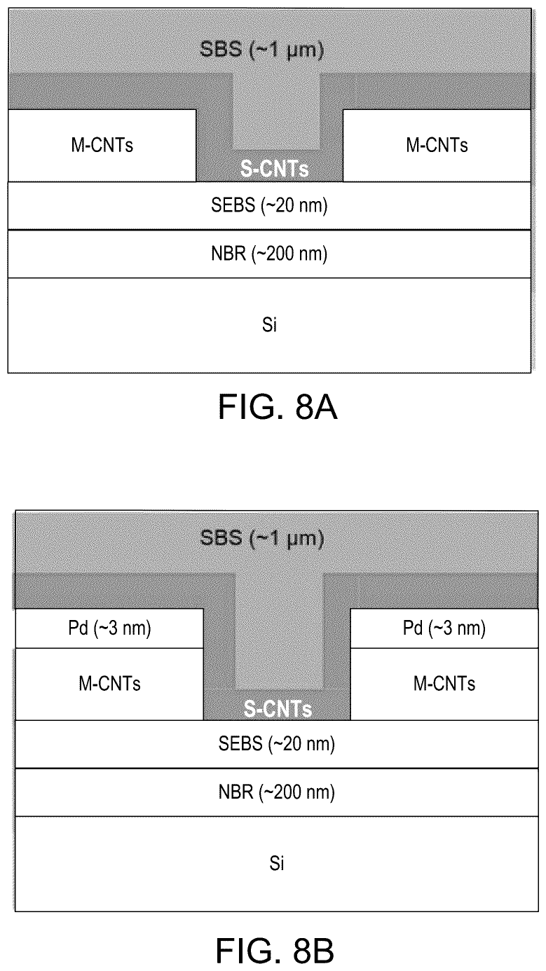

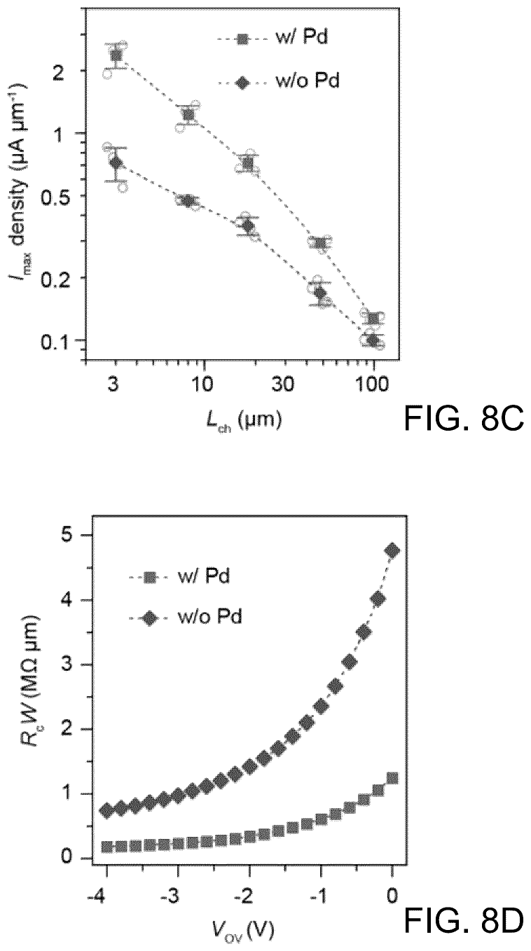

Turning now to the drawings, which are representative of some of the experimental examples, FIG. 1A is a three-dimensional view of an exemplary intrinsically stretchable semiconductor, CNT transistor. The transistor can be a thin-film transistor and include a stretchable substrate, a bottom gate electrode, a gate dielectric, source and drain electrodes, an S-CNT channel, a channel encapsulation, and interconnect connected to the source and drain electrodes. Portions of an interface material (not shown, see FIG. 8B) can be sandwiched between a surface of the channel and the source and drain electrodes in order to reduce contact resistance. Along with the channel having a dense semiconducting CNT path along a majority of a length between the source and drain electrodes, the interface material facilitates mobility of charge carriers during operation of the transistor.

Portions 130 and 132 of the source and drain electrodes are arranged along a plane that is parallel to and displaced form a plane along which surface 120 of the channel is arranged. Notably, surface 120 of the channel along a majority of the length between the source and drain electrodes is non-etched. The dielectric material is sandwiched by the channel and gate electrode as shown. From a side view of the semiconductor, it can be appreciated that device can also include contacts respectively connected to the source and drain electrodes (e.g., along a first plane), and the surface portion of the channel can be arranged along a second plane that intersects with at least one of the source and drain electrodes. The surface portion can include a surface, which is on a side of the channel facing the first plane, that is without etch-based damage or etch-based residual material.

As should also be apparent, by avoiding use of an etching step in the formation of the channel, a surface portion the channel can include a non-etched surface along a majority of a length between the first electrode and the second electrode. The channel can have a short channel length (e.g., that is characterized by a transconductance normalized by channel width of at least 0.8 nS μm⁻¹).

FIG. 1B is a top, microscopic view of a transistor consistent with the transistor of FIG. 1A. According to an example, the stretchable substrate is constructed with a styrene-ethylene-butylene-styrene (SEBS) elastomer, the gate electrode is a smooth, patterned PEDOT:PSS, and the gate dielectric is patterned NBR and SEBS, which is intrinsically-stretchable. Examples of non-ionic, dielectric materials that can be sandwiched by the gate and channel, include poly(isoprene), poly(butyldiene), and poly(methyl methacrylate)-poly(butyldiene)-poly(methyl methacrylate), which may be crosslinked or photo-patterned. The source and drain electrodes include M-CNTs and an interface material, the channel encapsulation includes a styrene-butadiene-styrene (SBS) elastomer, and the interconnect includes a high conductivity material, such as a eutectic gallium-indium alloy (E-GaIn). The semiconductor is at least partially intrinsically-stretchable due to material of the semiconducting CNTs forming a network.

In certain examples, the semiconductor can be at least partially intrinsically-stretchable due to material of the semiconducting CNTs forming a network. Another intrinsically-stretchable layer can be arranged adjacent to a portion of material including the channel, the distance between the source and drain electrodes can be in the range from 100 nm to 10 micron, and at least one of the source and drain electrodes includes a combination of one or more of: metallic CNTs and material having metal and polymer. The channel can be composed of a material that is susceptible to damage from a plasma etching process. In other structures, the distance between the source and drain electrodes can be in the range from 100 nm to 400 nm. At an interim stage of manufacture of the semiconductor, the semiconductor can include a patterning structure in which at least a portion of one of the source and drain electrodes is composed of a material having metal-CNTs.

FIG. 1C illustrates chemical structures in the transistor of FIGS. 1A and 1B. The illustrated structures show NBR, pentaerythritol tetra(3-mercaptopropionate) (PETMP), SEBS, SBS, C10-azide, PEDOT-PSS, and PR-PEGMA. PETMP is used as the crosslinker in a direct photo-patterning process using a thiol-ene reaction. PR-PEGMA is used with PEDOT:PSS for purposes of forming a crosslinked network and making the PEDOT:PSS dissolvable in water, then photolithography can be used on PEDOT:PSS; enable stretchability of PEDOT:PSS; and improve conductivity.

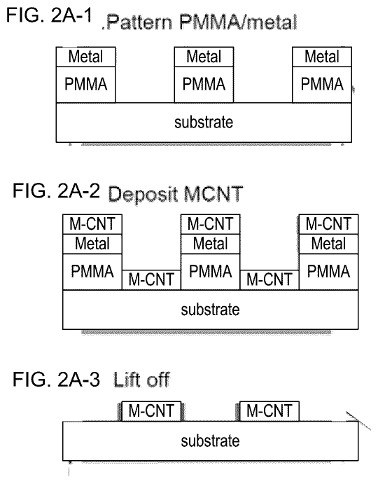

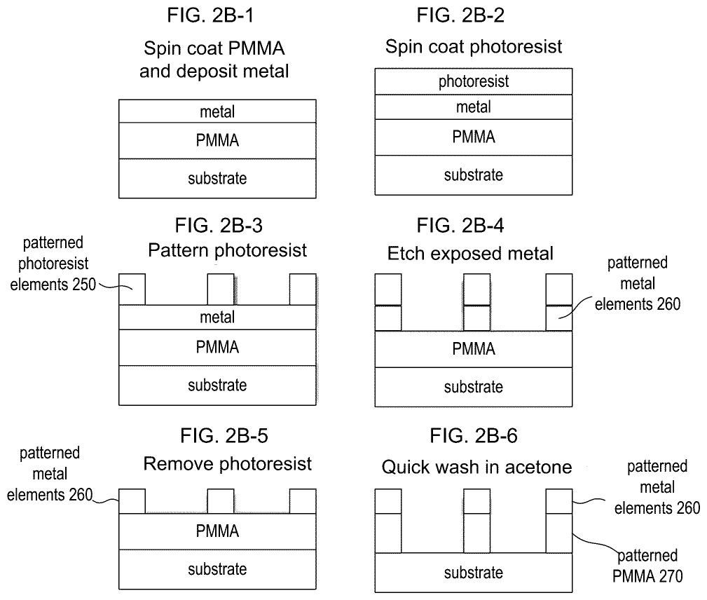

FIG. 1D-1 through FIG. 1D-6 illustrate structures produced by a process flow for fabricating a high-performance intrinsically stretchable semiconductor. Additional details are found elsewhere in this document for stages in the process. FIG. 1D-1 shows the preparation of the substrate. FIG. 1D-2 shows the patterning of an array of gate electrodes. FIG. 1D-3 shows the patterning of gate dielectric over the gate electrodes. FIG. 1D-4 shows the patterning of source and drain electrodes corresponding to the array of gate electrodes. According to an example, the source and drain electrodes can be separated from each other by a distance (ref. number 150) that spans at least a portion of the channel and is in a range of 100 nm to 50,000 nm. FIG. 1D-5 shows the patterning of channel material in the channels corresponding to the array of source-drain-gate structures. The channel can be composed of a material that is susceptible to damage from a plasma etching process FIG. 1D-6 shows the patterning of the interconnect material that connects to the source and drain electrodes.

To achieve high driving current in a transistor without increasing the device area or power consumption benefits from the following: high-mobility semiconductor, low S/D contact resistance, and high gate dielectric capacitance with low defect states. For the S/D electrodes, previous PEDOT:PSS-related processes suffered from poor charge injection, resulting in substantially degraded field-effect mobility compared to non-stretchable metal electrodes. CNT network electrodes with a metal interfacial layer have achieved contact resistance similar to those made by metals as a result of properly maintained charge injection.

Previous methods to pattern M-CNT electrodes relied on the use of a shadow mask, which suffered from poor resolution (typically >50 μm). Even when using photoresist patterned masks for direct M-CNT lift-off, smooth boundaries and small channel lengths were unachievable. A metal-assisted lift-off process for patterning M-CNT as contact electrodes achieves such smooth boundaries and small channel lengths. At least a portion of one of the source and drain electrodes in the patterning structure is composed of a material having metal CNTs. The patterning processes described herein for formation of the CNT S/D electrodes can be combined with other processes used in the fabrication of S/D electrodes in stretchable polymer semiconductors.

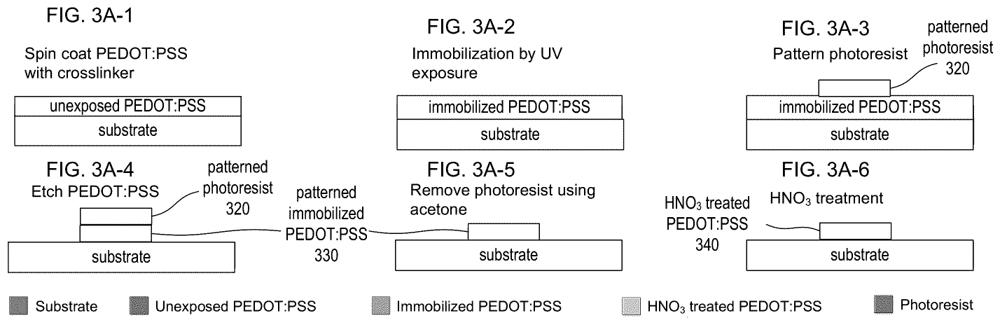

FIGS. 2A-1, 2A-2, and 2A-3 illustrate structures produced by a process flow for patterning M-CNT electrodes. Briefly, the process involves the patterning of a stacked poly(methyl methacrylate) (PMMA)/copper (Cu) structure as shown in FIG. 2A-2, followed by the deposition of M-CNT by spray coating as shown in FIG. 2A-2. FIG. 2A-3 illustrates patterning of M-CNT/Pd as stretchable source/drain electrodes via the disclosed metal-assisted lift-off process. This method allowed us to achieve L_{ch} as small as ˜0.9 μm due to the sharp edges created by the metal-layer-assisted lift-off process, which enabled sub-micrometer patterning of M-CNT.

The process of making PMMA/metal stack structures, as shown in FIG. 2A-1 is further illustrated in FIGS. 2B-1 through 2B-6. FIG. 2B-1 shows the structure resulting from spin-coating PMMA 495K A4 (40 mg/ml in anisole, MicroChem) onto the substrate at 800 rpm for 90 s, and then at 4000 rpm for 20 s. The metal layer can be a 150 nm-thick Cu thin film deposited by e-beam evaporator at a deposition rate of 1.2 Å/s. Next, AZ® 1512 was spin-coated at 4000 rpm for 45 s, and immediately after the structure was exposed at dose of 110 mJ/cm2 using MicroWriter ML3, and then developed in MF319 for 45 s, rinsed by deionized (DI) water and dried by N₂, as shown in FIG. 2B-2. FIG. 2B-3 shows patterning of the layer of photoresist The structure was then immersed into in FeCl3 solution for 5 s to etch the Cu (the original Cu etchant, MG Chemicals 415-1L ferric chloride copper etchant solution, was 1:20 diluted in DI water), washed by DI water and dried by N₂, which is shown by FIG. 2B-4. FIG. 2B-5 shows the structure after removal of the photoresist. After drying, the structure was flood-exposed in a UV curing system (365 nm) at dose of around 120 mJ/cm2, and then developed in MF319 for 1 min, rinsed by DI water and dried by N₂. The structure was then immersed into acetone to etch PMMA in acetone for 1 s, and rinsed by IPA for 10 s, dried by N₂ as shown by the structure of FIG. 2B-6. P3-SWNT was then spray-coated onto the structure placed on a hotplate held at 80 degrees C. The final sheet resistance of M-CNT was around 1-3 kΩ/sq. M-CNT solution was prepared by dispersing 80 mg P3-SWNT in 300 mL IPA and 30 ml DI water through a consecutive 5-hour bath sonication, followed by a 30-minute tip sonication and then centrifugation at 6000 rpm for 30 min. To reduce the contact resistance to <1 MΩ μm, 3 nm Pd was deposited by thermal evaporation followed by a lift-off in acetone.

As should be apparent in view of the preceding and following discussion, the semiconductor can include a stretchable layer portion in which the channel resides, and the stretchable layer portion can include multiple layers. Each of the multiple layers can be composed of a stretchable polymer-based material. The channel can have a length of <10 μm and a thickness of not greater than 10 nm. The transistor can be configured to operate with a contact resistance <1 MΩ μm and high carrier mobility characterized as being greater than 10 cm²/Vs.

FIGS. 3A-1 through 3A-6 show structures made in a process of preparing a bottom gate (BG) of an intrinsically stretchable transistor. A bottom-gate (BG) rather than top-gate (TG) structure is used, because the spray-coated M-CNT electrodes may poke through the thin dielectric elastomer, resulting in a large gate leakage. Instead, spin-coated PEDOT:PSS with a surface roughness of only 1.3 nm can be used as the BG to eliminate the shorting issue. To achieve high stretchability and conductivity simultaneously, crosslinked PEDOT:PSS with a topological supramolecular crosslinker based on polyrotaxnes (PR) can be used. Using photolithography and oxygen plasma etching, the UV crosslinked PEDOT:PSS/PR film can be patterned to give a gate length as small as ˜0.8 μm, while the directly photo-patterned PEDOT:PSS electrodes are limited to 2 μm feature sizes.

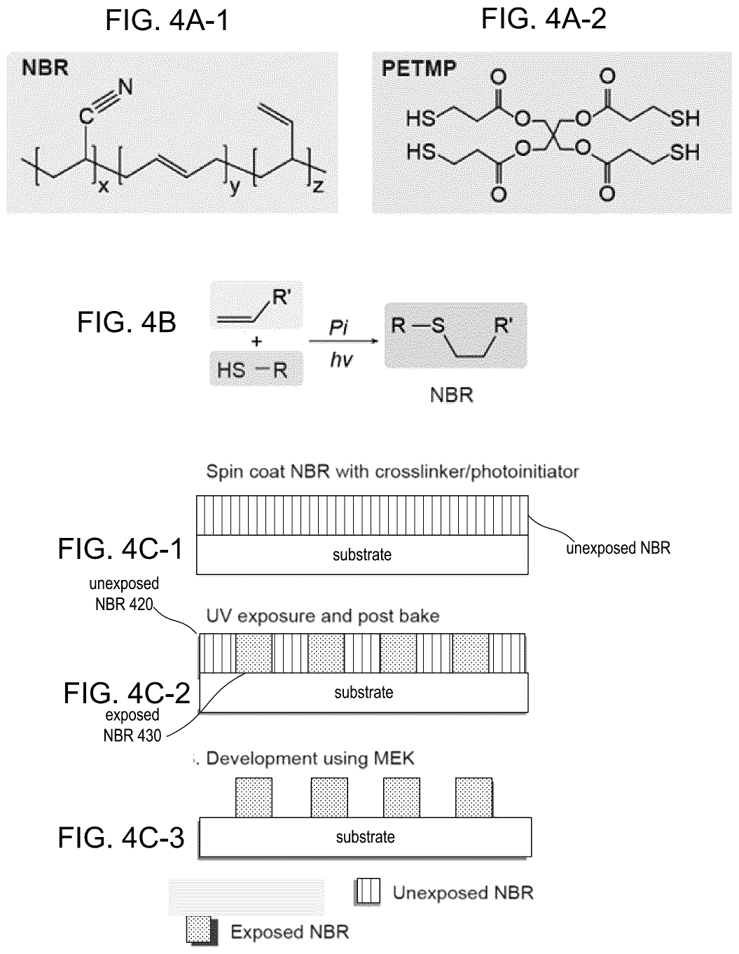

FIG. 3A-1 shows the structure resulting from spin coating PEDOT:PSS/PR on a substrate at 3000 rpm. Polyrotaxane-based supramolecular crosslinker (50 mg/ml) and the photoinitiator LAP (1.5 mg/ml) were mixed into PEDOT:PSS PH1000 solution, and then diluted by DI water (PEDOT:DI water ratio is 2:1). The structure was then UV-exposed using Electro·Lite Corporation ELC-500 for 20 mins in glovebox (filled with N₂) and treated by HNO₃ (6 mol/L) for 20 s, washed by DI water, and dried by N₂ to produce the structure of FIG. 3A-2. The structure of FIG. 3A-2 was then baked at 150 degrees C. for 10 mins, and then AZ1512 was spin coated at 4000 rpm, the solvent was removed in a vacuum desiccator for 10 mins, exposed at a dose of 110 mJ/cm2 using ML3, developed in MF319 for 1 min, rinsed by DI water and dried by N₂, and the photoresist layer was patterned as shown by FIG. 3A-3. Next, the PEDOT:PSS/PR was etched for 110 s by oxygen plasma at 150 W power (March Instruments PX-250 Plasma Asher) as shown in the structure of FIG. 3A-4. Once the PEDOT:PSS/PR has been etched, the pattered photoresist was removed by sonication in acetone, the structure rinsed with IPA and then dried with N₂, as shown by the structure of FIG. 3A-5. The patterned, immobilized PEDOT:PSS was treated by HNO₃ (6 mol/L) for 20 s, washed by DI water, and dried by N₂, and the resulting structure is shown in FIG. 3A-6. Because the PEDOT:PSS film could absorb moisture in the air, which can reduce the adhesion of the photoresist and induce additional stresses. As a result, the photoresist could be stripped off or cracked at the edges. Prebake before spinning coating the photoresist is necessary to remove moisture and enable good adhesion and hence high-resolution patterning of photoresist on PEDOT:PSS.

FIGS. 4A-1 through 4A-2, FIG. 4B, and FIGS. 4C-1 through 4C-3 illustrate patterning of a gate dielectric consistent with the stretchable semiconductor disclosed herein. To ensure a low operation voltage for safe and efficient on-skin applications, a high-κ elastomer NBR (FIG. 4A-1, κ>20) can be used to provide high gate dielectric capacitance. Taking advantage of the C═C bonds in NBR, a direct photo-patterning process uses a thiol-ene reaction (FIG. 4B) with pentacrythritol tetra(3-mercaptopropionate) (PETMP, FIG. 4A-2) as the crosslinker. FIG. 4C-1 shows a layer of unexposed NBR that has been spin-coated on a substrate. FIG. 4C-2 shows the patterning of UV-exposed NBR on a baked structure. FIG. 4C-3 shows the structure removal of the unexposed NBR.

FIG. 5A-1 through FIG. 5A-4 Schematic diagram showing the process of patterning low-κ SEBS dielectric layer based on photolithography and oxygen plasma etching. Cu was used to protect other areas. This method can be used to pattern low-κ polymer stretchable dielectric SEBS using a more convenient direct-writing lithography tool with 385 nm wavelength other than a UV lamp with 254 nm wavelength.

To passivate the polar NBR surface (which usually leads to a high density of defects at the dielectric-semiconductor interface and degrades charge transport performance), a thin layer (˜50 nm) of low-κ styrene-ethylene-butylene-styrene (SEBS) elastomer was spin-coated, crosslinked and then patterned through metal mask-protected oxygen plasma etching.

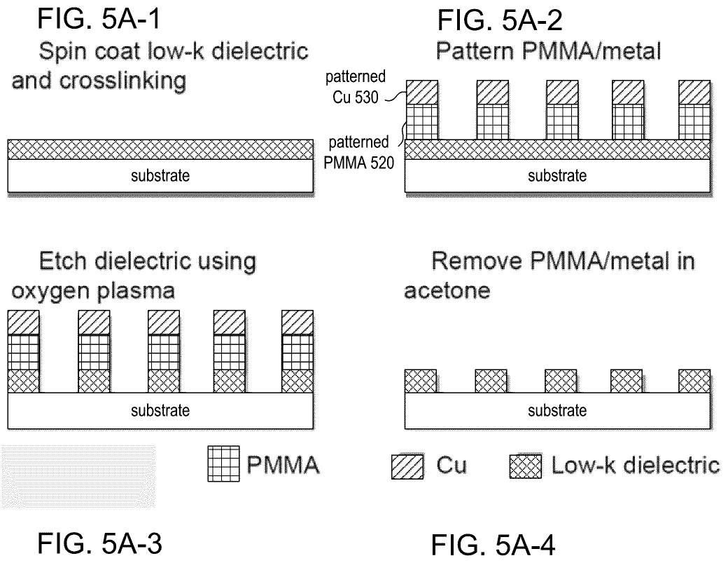

FIG. 5A-1 shows the low-κ dielectric having been spin-coated on the substrate. Unexposed NBR (40 mg/ml in cyclohexanone with 4 wt % PETMP and 4 wt % BAPO vs NBR) was spin-coated on a substrate at 1500 rpm for 90 s, and then at 4000 rpm for 30 s. The substrate and unexposed NBR layer were exposed at a dose of 200 mJ/cm2 by ML3, baked at 60 degrees C. for 2 mins, developed using MEK, and then baked at 150 degrees C. for 30 mins in the glovebox. Then, low-K dielectric SEBS (10 mg/ml in toluene with 4 wt % C10-azide) was spin-coated at 1000 rpm, and bake at 150 degrees C. for 1 h, washed by toluene, and dried by N₂. Following formation of the low-κ dielectric layer, PMMA 495K was spin-coated on the structure 800 rpm, and 150 nm-thick Cu was deposited by an e-beam evaporator at a deposition rate of 1.2 Å/s.

The patterned metal and PMMA are shown in the structure of FIG. 5A-2. AZ 1512 was spincoated at 4000 rpm, and the sample was exposed at a dose of 110 mJ/cm2 using ML3, and then developed in MF319 for 45 s, rinsed by DI water and dried by N2. (6) The sample was immersed into in a FeCl3 solution for 5 s to etch Cu (the original Cu etchant, MG Chemicals 415-IL ferric chloride copper etchant solution, was 1:20 diluted in DI water), rinsed by DI water and blow dried by N2. (7) The sample was flood-exposed in a UV curing system at a dose of around 120 mJ/cm2, and then developed in MF319 for 1 min, rinsed by DI water and dried by N2. (8) The sample was immersed into acetone to etch PMMA in cold acetone for 1 s, and rinsed by IPA for 10 s, dried by N2. The exposed low-κ dielectric was etched for 30 s by oxygen plasma with a power of 150 W (March Instruments PX-250 Plasma Asher), resulting in the structure of FIG. 5A-3. The PMMA and Cu were removed in acetone to produce the structure of FIG. 5A-4.

High-mobility semiconductor is the key to high-drive capability of the transistors and integrated circuits. Compared to stretchable polymer semiconductors, S-CNT networks typically have higher charge-carrier mobilities. To form channel, S-CNT can be deposited onto a dextran film, which was then supported by a polymer coating, and then transferred them to the polymer dielectric. The saturation carrier mobility measured using the BG structure with gold (Au) contact electrodes reached ˜30 cm² V⁻¹ s⁻¹ for L_{ch} of 100 μm, which is similar to directly deposited S-CNT on SiO₂/Si substrate.

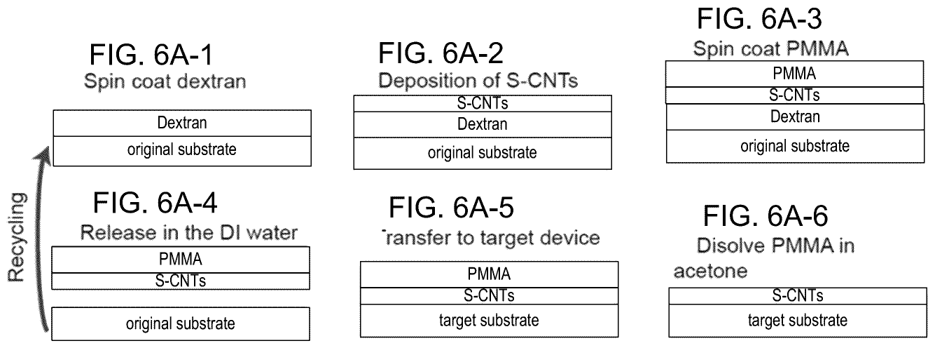

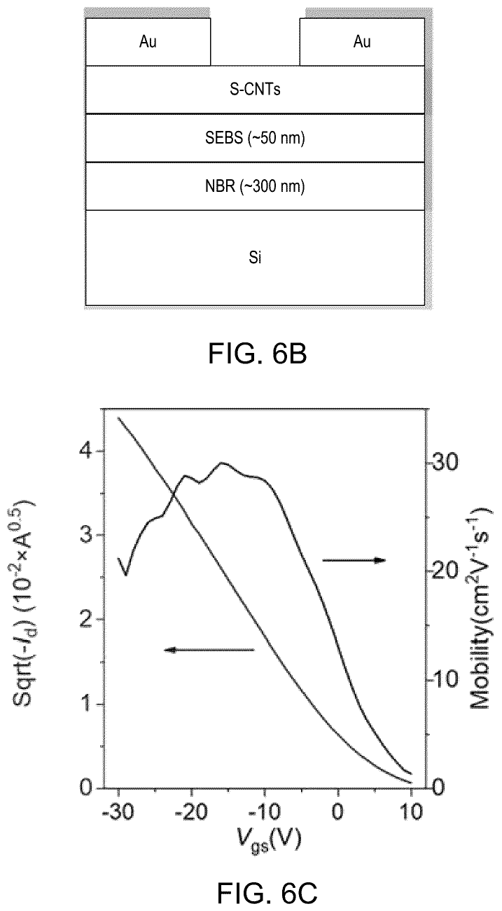

FIG. 6A-1 through FIG. 6A-6 illustrate structures made in the process of transferring of S-CNTs as a device channel. Dextran (50 mg/ml) was spin-coated onto Si/SiO2 substrate, baked at 150 degrees C. for 30 mins, and then immersed into high-semiconducting-purity CNT solution for 48 hours, resulting in the structure of FIG. 6A-1. An S-CNT solution was prepared by sonicating PFPD/CNT mixed solution (5 mg of PFPD and 5 mg of raw RN-020 SWNTs in 20 ml toluene) for 30 min at an amplitude level of 45% (Cole Parmer ultrasonicator 750 W) while externally cooling with a dry ice bath, centrifuging at 8000 rpm for 5 mins at 14 degrees C. to remove most of the un-dispersed residues, and centrifuging (Sorvall lynx 4000) at 17,000 rpm for 25 min at 14 degrees C. for further purification. 80% of the upper supernatants were collected for deposition on the Dextran layer (FIG. 6A-2). The substrate deposited with S-CNT was washed by toluene for 10 min twice, dried by N2, and then baked at 150 degrees C. for 30 min. PMMA 495K A4 (40 mg/ml in anisole) was spin coated onto the as-deposited S-CNT at 600 rpm for 90 s, and then at 4000 rpm for 20 s, and dried overnight at room temperature (FIG. 6A-3). A channel thickness of 2 nm thick s-CNT can achieve a mobility higher than 10 cm²/Vs). Four edges of the structure were fixed by polyimide tape, and the PMMA and S-CNT layers released from the original substrate in DI water (FIG. 6A-4). The released PMMA with S-CNT was attached to a target substrate, and then dried overnight at room temperature (FIG. 6A-5). The polyimide tapes were cut after transferring. PMMA was dissolved in acetone for 10 min. The transferred S-CNT film was washed in IPA for 2 min, blow dried by N2, washed in DI water for 1 min, and dried by N2. (5) The resulting structure (FIG. 6A-6) was baked at 150 degrees C. for 30 minutes in a glovebox.

FIG. 6B shows an exemplary semiconductor having Au contact electrodes and a channel having transferred S-CNTs disposed on a SEBS-NBR elastomer dielectric. The saturation carrier mobility measured using the BG structure with gold (Au) contact electrodes reached ˜30 cm² V⁻¹ s⁻¹ for L_{ch} of 100 μm, which is similar to S-CNTs directly deposited on a SiO₂/Si substrate. FIG. 6C is a graph showing field-effect mobility as a function of gate voltage for a transistor having transferred S-CNT onto the exemplary elastomer dielectric.

FIG. 7-1 through FIG. 7-6 illustrate structures made in the process of patterning S-CNTs.

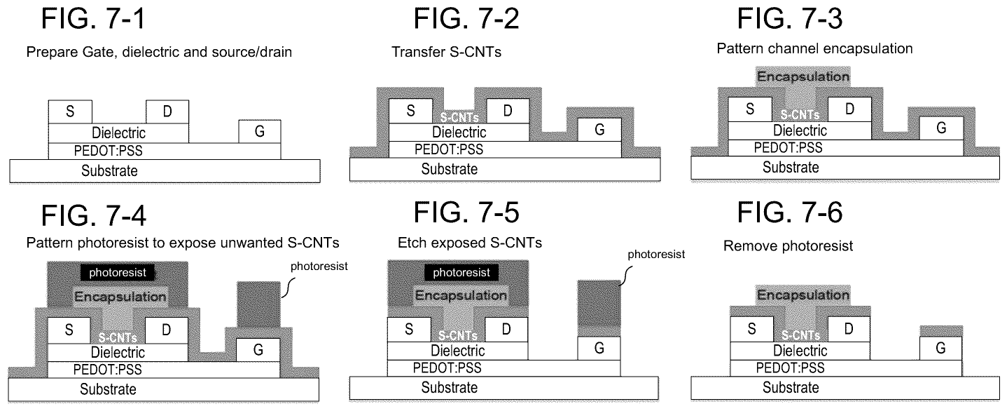

FIG. 7-1 shows a structure that includes the substrate, gate, dielectric, and source and drain electrodes having been patterned as disclosed herein. FIG. 7-2 shows the structure of FIG. 7-2 with S-CNTs having been transferred as described herein.

To pattern the S-CNTs, a layer of styrene-butadiene-styrene (SBS) elastomer (˜500 nm) is first deposited and patterned via thiol-ene reaction as the channel encapsulation, as shown by FIG. 7-3. The channel encapsulation prevents the contamination from the photoresist and improved stability of the device. In patterning the encapsulation, SBS (50 mg/ml in toluene with 4 wt % PETMP and 4 wt % BAPO vs SBS) was spin-coated at 1000 rpm for 90 s, and then at 4000 rpm for 30 s, exposed at a dose of 300 mJ/cm2 using ML3, baked at 60 degrees C. for 2 min, developed by cyclohexane, and baked at 120 degrees C. for 5 mins.

In patterning the photoresist, AZ 1512 was spin-coated at 4000 rpm. The residue solvent in the photoresist was removed by placing in a vacuum desiccator for 10 mins. The sample was exposed at a dose of 120 mJ/cm2 using ML3, and then developed in MF319 for 2 mins, rinsed by DI water and dried by N₂, with the patterned photoresist shown in FIG. 7-4.

The exposed S-CNT film was etched for 15 s by oxygen plasma with 150 W power (March Instruments PX-250 Plasma Asher), as shown by FIG. 7-5. The photoresist was removed by sonication in acetone, rinsed by IPA, and then dried by N₂. as shown by FIG. 7-6.

FIGS. 8A-8D show a comparison of the contact resistance in a structure not having a Pd interface material and a structure having a Pd interface material. According to the example, the interface material includes Pd. In alternative structures, the interface material can include one or a combination of two or more of the following palladium (Pd), gold (Au), platinum (Pt), titanium (Ti), and an organic dopant. Examples of organic dopants include F4-TCNQ, F6-TCNNQ, and/ or an N-type dopant (such as N-NBI).

Also in accordance with the present disclosure, FIG. 8A shows an exemplary semiconductor structure that does not include a Pd material, and FIG. 8B shows an exemplary semiconductor structure that includes a Pd material. Both structures include an Si substrate, an NBR-SEBS dielectric, a channel that includes S-CNTs, M-CNT source and drain electrodes, and SBS encapsulation. The semiconductor structure of FIG. 8B includes Pd interface material sandwiched between the S/D electrodes and the S-CNTs of the channel. Such a semiconductor can include a stretchable semiconductor that includes a channel that has a surface portion having semiconducting CNTs (carbon nanotubes). The source and drain electrodes can include a first electrode and a second electrode that are separated from each other by a distance that spans at least a portion of the channel and that is in a range from 100 nm to 50,000 nm. The semiconductor can include an interface material that is sandwiched between a first surface region of the channel and the first electrode and between a second surface region of the channel and the second electrode. The interface material is arranged to reduce contact resistance and, with the channel, facilitate mobility of charge carriers during operation of the semiconductor.

FIG. 8C is a graph that shows the scaling behavior of transistors consistent with the semiconductor structures of FIGS. 8A and 8B, and FIG. 8D is a graph that shows a comparison of contact resistances under different overdrive voltages for transistors consistent with the semiconductor structures of FIGS. 8A and 8B.

Considering the drain-source contacts, the existence of the Schottky barrier between M-CNTs and S-CNTs is expected to give a large contact resistance, which would limit the drive capability when scaling down the transistor channel length. To solve this issue, after spray coating M-CNTs, a thin Pd layer (3 nm) was deposited. The Pd layer has a band structure matched well with S-CNTs to enhance charge injection. Compared to pure M-CNTs, the added Pd interface material increased the electrode work function by 0.47 eV, leading to improved hole injection. It may be observed that the thermal deposition process of Pd is compatible with the disclosed metal-assisted lift-off process, whereas other methods, such as photo-crosslinking or etching, cannot easily achieve the same structure. With the Pd interface material, the transistors showed much higher drain current improvement as Len scaled down. Using the transfer length method to extract Re, it was observed that the Pd interface material reduced R_{c} by ˜80%.

FIG. 9A-1 through FIG. 9A-6 illustrate patterning of interconnects. To build a large-scale integrated circuit, the voltage loss from the interconnects should also be minimized. However, the sheet resistances of both M-CNT and PEDOT:PSS/PR electrodes are too high (˜1 kΩ sq⁻¹) for high-speed operation and large-scale integration. Therefore, EGaIn was introduced as the global interconnect, which resulted in a much-reduced sheet resistance of ˜0.2Ω sq⁻¹ and successfully patterned down to ˜2 μm width via a modified lift-off process.

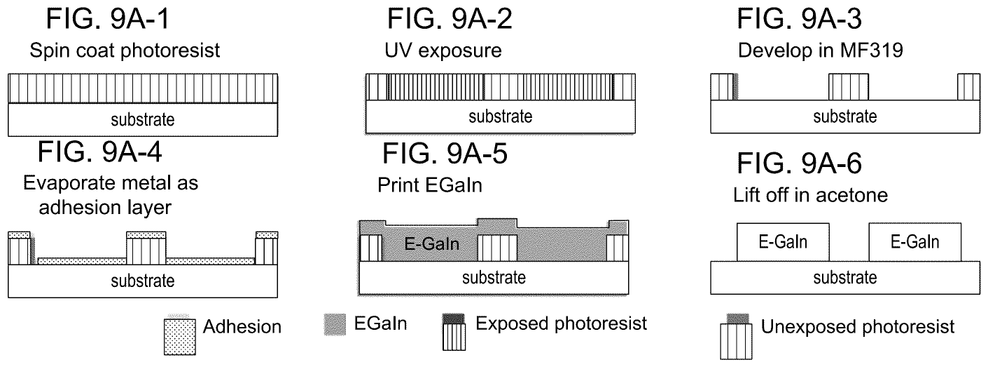

In pattering the interconnects, AZ 1512 photoresist was spin-coated at 4000 rpm (FIG. 9A-1), the solvent was removed in a vacuum desiccator for 10 mins, and the sample was exposed at dose of 130 mJ/cm2 using ML3 (FIG. 9A-2), and then developed in MF319 for 1 min (FIG. 9A-3), gently rinsed by DI water and dried by N₂. Cr/Au with a thickness of 3/40 nm was deposited via a thermal evaporator with deposition rates of 0.1/0.5 Å/s, as shown by FIG. 9A-4. EGaIn was printed onto the sample using a 1 mm thick PDMS film made by drop casting (FIG. 9A-5), to press through a PDMS film, and then remove excess EGaIn on photoresist using another PDMS film.

FIG. 9A-6 shows Lift off in acetone by ultra-sonication. Ultra-sonication enables small feature sizes to be obtained. The ultra-sonication method was adapted from previous methods in order to be compatible with soft substrates. Because of the large modulus mismatch between the photoresist (GPa) and the soft substrate (MPa), the edges of photoresist can easily form fractures during the development and rinsing process. To solve this issue, the sample can be immersed into the developer and DI water without any shaking, and then dried it by keeping the sample sitting vertical in air.

FIG. 10 shows a transistor having a bottom-gate, bottom-contact CNT-TFT. Silicon (Si), dextran, and styrene-butadiene-styrene block copolymer (SBS) materials serve as the supporting layer, releasing layer, and stretchable substrate, respectively. SBS substrate is crosslinked with pentaerythritol tetrakis (3-mercaptopropionate) (PETMP) to increase chemical resistance to later-stage solution processes. Poly (ethylene glycol)-block-poly(propylene glycol)-blockpoly (ethylene glycol) diacrylate is blended into poly (3,4-ethylenedioxythiophene): polystyrene sulfonate (PEDOT: PSS) to form a stretchable conducting double network, and then patterned via oxygen plasma etch to form the gate electrode. Nitrile butadiene rubber (NBR) is used as the gate dielectric. PETMP is blended into NBR to enable direct photopatterning. An unsorted m-CNT thin film (with 3 nm-thick palladium) is patterned via metal-assisted lift-off to make stretchable source/drain electrodes. A sorted semiconducting CNT (s-CNT) thin film as the semiconducting channel is transferred to the substrate and then lithographically patterned via oxygen plasma etch. An SBS layer is photo-patterned as the encapsulation layer. A liquid metal eutectic gallium-indium (EGaIn) layer is patterned via liftoff as the probe pads. Lastly, the CNT-TFTs are released in water and annealed at 120 degrees C. for 2 hours in the vacuum.

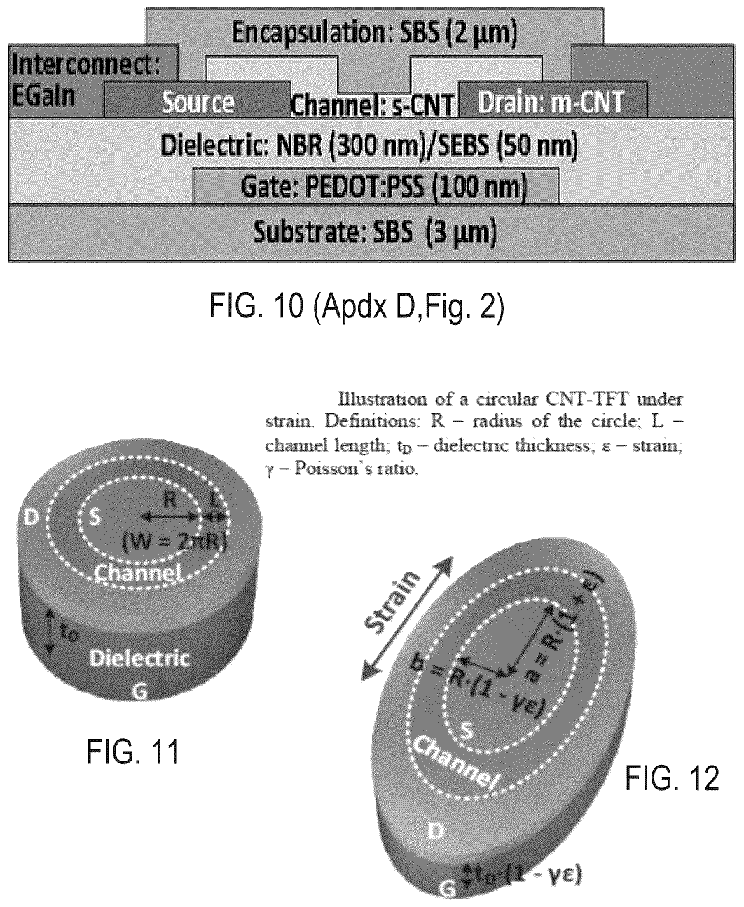

FIGS. 11 and 12 illustrate a circular CNT-TFT under strain. Rounded-corner CNT-TFTs (e.g., circular configurations) effectively cancel strain-induced changes (parallel and/or perpendicular to the channel) in on-current by incorporating various orientations within the channel. It will be appreciated that in alternative examples of the present disclosure, instead of strictly circular configurations, configurations with rounded corners (e.g., as far-perimeter boundaries of the channel that are curved or rounded) can be used. In addition, by using such circular or rounded-corner CNT-TFTs, the impact of strain becomes direction-independent as a result of the symmetry of the (e.g., circular) configuration. For example, the structure of the channel in a circular configuration in certain experiments was based on the observation of contrasting changes in the on-current when the transistor is oriented in the two orthogonal directions with respect to the strain. Compared with the traditional rectangle channels, the changes in device characteristics become significantly less pronounced.

When a strain ϵ is applied parallel to the channel, the channel length increases by ϵ, while the channel width and gate dielectric thickness decreases by γ ϵ, in accordance with the Poisson effect, where γ represents the Poisson's ratio of the substrate. When a strain is applied perpendicular to the channel, the geometric changes in the channel length and width occur in an opposite manner. Changes in CNT field-effect mobility can be characterized as a function of the angle θ, which represents the orientation of strain relative to the charge-carrier transport direction. We observe that when the strain is rotated away from the transport direction towards its perpendicularity (i.e., from θ=0 to 90 degrees), the mobility degrades. Also, as the strain magnitude increases, the degradation becomes more severe. A statistical comparison showed that at 30% strain, on average, the change of on-current decreases from 56% to 3% by using the circular layout. The shape of the channel can alternatively be elliptical.

To understand the strain effect on a circular channel, finite element-based 2D simulation in Comsol can be used. As shown in FIG. 12, the channel under strain is modeled as an oval shape (i.e., a circle under stretch), with the major and minor axes of R·(1+ϵ) and R·(1−γϵ), respectively, where R is the radius of the unstretched circle. The strain-induced changes in mobility are incorporated into the simulation as a function of both strain direction (relative to the charge-carrier transport direction) and magnitude, i.e., θ and ϵ, according to measured characterizations.

The simulated changes of on-current suggest that under strain, the current tends to concentrate at small θ's, resulting from the increased mobility at these regions. Extracted angular current density (i.e., dI_{ON}/dθ) confirmed the theory that the strain effect cancels out across the various orientations within the 360 degree Circle, resulting in stable on-current under strain for circular CNT-TFTs.

As should be apparent, in certain of the exemplary embodiments herein the channel extends along a plane and is characterized by a configuration that maintains physical resilience under strain in response to being stretched in a direction parallel to the plane or a direction perpendicular to a direction in which charge is transported. The configuration also facilitates cancellation of on-current variations across different segments of the channel.

Accordingly, many different types of processes and devices using the disclosed semiconductor structure may be advantaged by the examples disclosed herein as well as others, including the related examples in the above-identified U.S. Provisional Patent Applications. For example, the disclosed structures and methods may be suitable for applications outside those of human-machine interfaces. For example, devices consistent with structures and methods disclosed herein may suitable for applications related to physiologically-sensing wearables, human-machine interfaces, material-sensing apparatus that respond to stress and flexibility, user-implantable devices, as a backplane for shape-changing/stretchable displays, robotic skin, and soft robotics.

It is recognized and appreciated that as specific examples, the above-characterized figures and discussion are provided to help illustrate certain aspects (and advantages in some instances) which may be used in the manufacture of such structures and devices. These structures and devices include the exemplary structures and devices described in connection with each of the figures as well as other devices, as each such described embodiment has one or more related aspects which may be modified and/or combined with the other such devices and examples as described hereinabove may also be found in the respective Appendices of the above-referenced Provisional Applications.

The skilled artisan would also recognize various terminology as used in the present disclosure by way of their plain meaning. As examples, the Specification may describe and/or illustrates aspects useful for implementing the examples by way of various semiconductor materials/circuits which may be illustrated as or using terms such as layers, blocks, modules, device, system, unit, controller, and/or other circuit-type depictions. Further relative terms used herein such as approximately, about, “˜”, substantially, etc. refer to ranges of plus or minus 10% (unless otherwise indicated), and other terms such as “same” and “identical” will be understood by the skilled artisan has relating to two compared aspects for which there are no differences, and also in some instances which would be apparent given the context of the discussion, differences are not observable for the context at issue and/or for which there is no discernible difference in light of such context. Also, in connection with such descriptions, the term “source” may refer to source and/or drain interchangeably in the cases of a transistor structure and a semiconductor with multiple transistors or transistor-like structures (various types of devices with PN junctions including but not limited to multiple-FET structures and to optical devices such as LEDs), and in such contexts the terms source electrode and drain electrode may be referred to interchangeably with first electrode and second electrode. Such semiconductor and/or semiconductive materials (including portions of semiconductor structure) and circuit elements and/or related circuitry may be used together with other elements to exemplify how certain examples may be carried out in the form or structures, steps, functions, operations, activities, etc. It would also be appreciated that terms to exemplify orientation, such as upper/lower, left/right, top/bottom and above/below, may be used herein to refer to relative positions of elements as shown in the figures. It should be understood that the terminology is used for notational convenience only and that in actual use the disclosed structures may be oriented different from the orientation shown in the figures. For example, the channel may have one side oriented to face the circuit side of the semiconductor (i.e., the “contacts side” or the “circuit side” of the channel) and an opposite side (e.g., facing the substrate upon which the transistor is built up during manufacture). Thus, the terms should not be construed in a limiting manner.

Based upon the above discussion and illustrations, those skilled in the art will readily recognize that various modifications and changes may be made to the various embodiments without strictly following the exemplary embodiments and applications illustrated and described herein. For example, methods as exemplified in the Figures may involve steps carried out in various orders, with one or more aspects of the embodiments herein retained, or may involve fewer or more steps. Such modifications do not depart from the true spirit and scope of various aspects of the disclosure, including aspects set forth in the claims.

What is claimed:

1. An apparatus comprising:
a stretchable semiconductor having
a channel including a surface portion having semiconducting CNTs (carbon nanotubes),
source and drain electrodes including a first electrode and a second electrode separated from each other by a distance that spans at least a portion of the channel and that is in a range from 100 nm to 50,000 nm, and
an interface material, sandwiched between a first surface region of the channel and the first electrode and between a second surface region of the channel and the second electrode, to reduce contact resistance and, with the channel, facilitate mobility of charge carriers during operation of the semiconductor.

2. The apparatus of claim 1, wherein the semiconductor is at least partially intrinsically-stretchable due to material of the semiconducting CNTs forming a network, and the apparatus further includes at least one other intrinsically-stretchable layer arranged adjacent to a portion of material including the channel, the distance is in the range from 100 nm to 10 micron, and at least one of the source and drain electrodes includes one or more of: metallic CNTs and material having metal and polymer, and wherein the channel is composed of a material that is susceptible to damage from a plasma etching process.

3. The apparatus of claim 1, wherein the semiconductor, at an interim stage of manufacture of the semiconductor, includes a patterning structure, including at least a portion of one of the source and drain electrodes, composed of a material having metal-CNTs.

4. The apparatus of claim 1, wherein the semiconductor includes a stretchable layer portion in which the channel resides and further including multiple layers, each of the multiple layers composed of a stretchable polymer-based material, wherein the channel has a length of <10 μm and a thickness of not greater than 10 nm, and, the transistor is to operate with a contact resistance <1 MΩ μm and high carrier mobility characterized as being greater than 10 cm²/Vs.

5. The apparatus of claim 1, wherein the channel includes a non-etched, surface of the surface portion along a majority of a length between the first electrode and the second electrode.

6. The apparatus of claim 1, further including contacts respectively connected to the source and drain electrodes and along a first plane, wherein the surface portion of the channel is along a second plane that intersects with at least one of the source and drain electrodes, and the surface portion includes a surface, on a side of the channel facing the first plane, that is without etch-based damage or etch-based residual material.

7. The apparatus of claim 1, wherein the semiconductor further includes at least one dielectric material that is non-ionic and sandwiched by the channel and a gate electrode.

8. The apparatus of claim 1, wherein the distance is in a range from 100 nm to 400 nm.

9. The apparatus of claim 1, wherein the channel has a shape that is circular or elliptical.

10. The apparatus of claim 1, wherein the channel has a shape that is to facilitate cancellation of on-current variations and that corresponds to a shape with a plurality of far-perimeter boundaries that are curved or rounded.

11. The apparatus of claim 1, wherein the interface material includes one or a combination of two or more of the following: palladium (Pd), gold (Au), platinum (Pt), titanium (Ti), and an organic dopant.

12. The apparatus of claim 1, wherein at least portions of the first electrode and the second electrode are arranged along a plane that is parallel to a different plane along which a surface of the channel is arranged.

13. The apparatus of claim 1, wherein the first electrode and the second electrode are arranged along a plane that is parallel to, and displaced relative to, a plane along which a surface of the channel is arranged.

14. The apparatus of claim 1, wherein the channel extends along a plane and is characterized by a configuration that is to:
maintain physical resilience under strain in response to being stretched in at least one of a direction parallel to the plane and a direction perpendicular to a direction in which charge is transported; and
facilitate cancellation of on-current variations across different segments of the channel.

15. The apparatus of claim 1, wherein the CNTs are characterized at least in part by a field-effect mobility in a range from 1 cm²/Vs to 100 cm²/Vs, and the channel has a profile characterized by a dense semiconducting CNT path along a majority of a length between the first electrode and the second electrode.

16. The apparatus of claim 1, wherein the channel has a short channel length that is characterized by a transconductance normalized by channel width of at least 0.8 nS μm⁻¹.

17. The apparatus of claim 1, further including patterned metallic contact electrodes, connected to the source and drain electrodes, including at least one of M-CNTs, a metal layer, and an organic dopant.

18. The apparatus of claim 1, wherein the channel and the source and drain electrodes are part of a transistor, and the surface portion of the channel includes a non-etched material surface having semiconducting CNTs.

19. An apparatus comprising:
a semiconductor including:
a channel characterized by including material having sorted semiconducting carbon nanotubes (S-CNTs), and by a shape that is to facilitate cancellation of on-current variations;
source and drain electrodes including a first electrode and a second electrode separated from each other by a distance that spans at least a portion of the channel and that is in a range from 100 nm to 50,000 nm;
an interface material, sandwiched between a first surface region of the channel and the first electrode and between a second surface region of the channel and the second electrode, to reduce contact resistance and, with the channel, facilitate mobility of charged carriers during operation of a transistor including the channel; and
metallic contact electrodes secured to the source and drain electrodes and including at least one of S-CNTs and palladium, wherein the channel is part of a thin-film transistor that is to operate in steady state at one or more switching frequencies of at least 10 kHz, and the channel is further characterized by a portion having a plurality of rounded corners.

20. A method comprising:
in a semiconductor including having a channel including semiconducting CNTs (carbon nanotubes) material, and having source and drain electrodes separated from each other by a distance that spans at least a portion of the channel and that is in a range from 100 nm to 50,000 nm, causing current to pass between the source and drain electrodes and through the channel, while using an interface material, sandwiched between a first surface region of the channel and the source electrode and between a second surface region of the channel and the drain electrode, to reduce contact resistance and, with the channel, facilitate a high charge-carrier mobility.

21. The method of claim 20, further including providing for an interim stage of manufacture of the semiconductor a patterned structure, including at least a portion of one of the source and drain electrodes, composed of a material having metal-CNTs, and providing a surface of the channel that faces a plane along which the source and drain electrodes are to interface with at least one of a plurality of contacts and that is without etch-based damage or etch-based residual material.

22. The method of claim 20, wherein the semiconductor is intrinsically-stretchable and the method further includes subjecting the semiconductor to more than a level of strain, in a range from 60% strain to 100% strain, thereby causing the semiconductor to stretch, and concurrently:
operating the semiconductor in steady state at one or more switching frequencies of at least 10 kHz; and causing the current to pass between the source and drain electrodes and through the channel with a charge-carrier mobility of at least 10 cm²/Vs.

23. The method of claim 21, wherein the charge-carrier mobility is in a range from 10 cm²/Vs to 100 cm²/Vs.

24. The method of claim 20, wherein the channel has a non-etched, smooth surface region between the source and drain electrodes.

25. An apparatus comprising:
a stretchable semiconductor having
a channel including a surface portion having semiconducting CNTs (carbon nanotubes),
a first electrode and a second electrode separated from each other by a distance that spans at least a portion of the channel and that is in a range from 100 nm to 50,000 nm, and
an interface region to reduce contact resistance and facilitate mobility of charge carriers during operation of the semiconductor, the interface region including respective interface portions between the channel and the first electrode and between the channel and the second electrode and including a surface region of the channel that is without etch-based damage or etch-based residual material and that is between the first and second electrodes and on the contacts side of the channel.
